(19) United States
(12) Patent Application Publication
(10) Pub. No.: US 2026/0068201 A1
(43) Pub. Date: Mar. 5, 2026

(54) SEMICONDUCTOR DEVICE AND MANUFACTURING METHOD OF SEMICONDUCTOR DEVICE

(71) Applicant: Renesas Electronics Corporation, Tokyo (JP)

(72) Inventor: Shunichi NAKAMURA, Tokyo (JP)

(21) Appl. No.: 19/253,507

(22) Filed: Jun. 27, 2025

(30) Foreign Application Priority Data
Sep. 4, 2024 (JP) 2024-151987

(51) Int. Cl. H10D 12/00; H10D 12/01; H10D 62/10; H10D 64/00; H10D 64/23

(52) U.S. Cl. CPC H10D 12/415; H10D 12/035; H10D 12/038; H10D 12/481; H10D 62/107; H10D 64/111; H10D 64/232

(57) ABSTRACT

A semiconductor device includes a semiconductor substrate having an upper surface and a lower surface, an element region containing a semiconductor element and a peripheral region surrounding the element region in plan view. The semiconductor substrate in the peripheral region includes an N-type drift layer, an N++ type channel stop layer disposed on the upper surface side relative to the N-type drift layer, which channel stop layer is at least one annular N++ type channel stop layer surrounding the element region, and an N type guard ring layer disposed on the upper surface side relative to the N-type drift layer.

### CROSS-REFERENCE TO RELATED APPLICATIONS

The disclosure of Japanese Patent Application No. 2024-151987 filed on Sep. 4, 2024, including the specification, drawings and abstract is incorporated herein by reference in its entirety.

### BACKGROUND

This disclosure relates to a semiconductor device and a method for manufacturing the semiconductor device.

There is a disclosed technique listed below.
[Patent Document 1] Japanese Unexamined Patent Application Publication No. 2024-003808

Patent Document 1 describes a semiconductor device having an IGBT (Insulated Gate Bipolar Transistor).

### SUMMARY

There is a desire to reduce the size of semiconductor devices. For example, it is desired to reduce the size of a semiconductor device without increasing the process cost of the IGBT and without compromising the negative charge tolerance of the IGBT. In this specification, the term “negative charge tolerance” refers to the limit of the amount of negative charge that can reach the surface of the semiconductor device during use, without causing the device to fail to maintain a predetermined breakdown voltage.

Other challenges and novel features will become apparent from the description of this specification and the accompanying drawings.

According to one embodiment, a semiconductor device comprises a semiconductor substrate having a first main surface and a second main surface opposite the first main surface. The semiconductor substrate, in plan view from the first main surface side, comprises: an element region containing a semiconductor element; and a peripheral region surrounding the element region. The semiconductor substrate in the peripheral region includes: a drift layer of a first conductivity type; at least one annular channel stop layer of the first conductivity type arranged on the first main surface side relative to the drift layer, which annular channel stop layer surrounds the element region; and at least one annular guard ring layer of the first conductivity type arranged on the first main surface side relative to the drift layer, which annular guard ring layer is arranged between an outermost peripheral structure within an interior surrounded by the channel stop layer and the channel stop layer in plan view. The outermost peripheral structure includes at least one of an annular semiconductor layer of a second conductivity type arranged on the first main surface side relative to the drift layer in the semiconductor substrate, and an annular field plate containing conductive material arranged on the first main surface side relative to the semiconductor substrate. A concentration of impurities of the first conductivity type in the guard ring layer is greater than a concentration of impurities of the first conductivity type in the drift layer and less than a concentration of impurities of the first conductivity type in the channel stop layer.

According to one embodiment, a method of manufacturing a semiconductor device, comprises: setting an element region including a semiconductor element and a peripheral region surrounding the element region in a semiconductor substrate having a first main surface and a second main surface opposite the first main surface, in plan view from the first main surface side; forming, in the peripheral region of the semiconductor substrate, a drift layer of a first conductivity type and at least one annular channel stop layer of the first conductivity type arranged on the first main surface side relative to the drift layer, which annular channel stop layer surrounds the element region; and forming at least one annular guard ring layer of the first conductivity type arranged on the first main surface side relative to the drift layer, which annular guard ring layer is arranged between an outermost peripheral structure within an interior surrounded by the channel stop layer and the channel stop layer. In forming the guard ring layer: the outermost peripheral structure is made to include at least one of an annular semiconductor layer of a second conductivity type arranged on the first main surface side relative to the drift layer in the semiconductor substrate, and an annular field plate containing conductive material arranged on the first main surface side relative to the semiconductor substrate; and a concentration of impurities of the first conductivity type in the guard ring layer is made to be greater than a concentration of impurities of the first conductivity type in the drift layer and less than a concentration of impurities of the first conductivity type in the channel stop layer.

According to the embodiment, it is possible to provide a semiconductor device and a method for manufacturing a semiconductor device that can reduce the size.

### BRIEF DESCRIPTION OF THE DRAWINGS

FIG. 1 is a plan view illustrating a semiconductor device according to Embodiment 1.

FIG. 2 is a cross-sectional view illustrating the peripheral region in the semiconductor device according to Embodiment 1, showing the cross-section along line II-II in FIG. 1.

FIG. 3 is an enlarged cross-sectional view illustrating the peripheral region in the semiconductor device according to Embodiment 1, showing the cross-section along plane III in FIG. 2.

FIG. 4 is a cross-sectional view illustrating the element region in the semiconductor device according to Embodiment 1, showing the cross-section along line IV-IV in FIG. 1.

FIG. 5 is a cross-sectional view illustrating the manufacturing process of the peripheral region in the method for manufacturing a semiconductor device according to Embodiment 1.

FIG. 6 is a cross-sectional view illustrating the manufacturing process of the element region in the method for manufacturing a semiconductor device according to Embodiment 1.

FIG. 7 is a cross-sectional view illustrating the manufacturing process of the element region in the method for manufacturing a semiconductor device according to Embodiment 1.

FIG. 8 is a cross-sectional view illustrating the manufacturing process of the element region in the method for manufacturing a semiconductor device according to Embodiment 1.

FIG. 9 is a cross-sectional view illustrating the manufacturing process of the element region in the method for manufacturing a semiconductor device according to Embodiment 1.

FIG. 10 is a cross-sectional view illustrating the manufacturing process of the element region in the method for manufacturing a semiconductor device according to Embodiment 1.

FIG. 11 is a cross-sectional view illustrating the peripheral region in the semiconductor device according to Comparative Example 1.

FIG. 12 is a cross-sectional view illustrating the peripheral region in the semiconductor device according to Comparative Example 2.

FIG. 13 is a cross-sectional view illustrating the peripheral region in the semiconductor device according to Comparative Example 3.

### DETAILED DESCRIPTION

For clarity of explanation, the following description and drawings are appropriately omitted and simplified. In the drawings, hatching may be omitted even in the case of cross-sectional views if it would otherwise become complicated or if the distinction from voids is clear. In each drawing, the same elements are denoted by the same reference numerals, and repetitive descriptions are omitted as necessary. Also, reference numerals are omitted as appropriate to prevent the drawings from becoming cluttered.

In this specification, when the conductivity type of a semiconductor is N type, it means that electrons are the only charge carriers, or both electrons and holes are charge carriers, but the concentration of electrons is higher than that of holes, making electrons the main charge carriers. Similarly, when the conductivity type of a semiconductor is P type, it means that holes are the only charge carriers, or both electrons and holes are charge carriers, but the concentration of holes is higher than that of electrons, making holes the main charge carriers.

Note that N++ type and P++ type indicate low-resistance N type and P type conductivity, respectively. N+ type and P+ type have higher resistance than N++ type and P++ type, but lower resistance than N type and P type conductivity. P− type and N-type indicate higher resistance N type and P type conductivity than N type and P type, respectively. Therefore, N type and P type indicate N type and P type conductivity with resistance between N+ type and P+ type and N− type and P− type, respectively. N+ type and P+ type indicate N type and P type conductivity with resistance between N++ type and P++ type and N type and P type, respectively. Unless otherwise specified, the same meaning applies.

The N type conductivity may be referred to as the first conductivity type, and the P type conductivity may be referred to as the second conductivity type. Conversely, the N type conductivity may be referred to as the second conductivity type, and the P type conductivity as the first conductivity type. Furthermore, semiconductor devices with reversed conductivity types of each configuration in this disclosure are also within the scope of the technical concept of this disclosure. Additionally, the resistance of each semiconductor layer of N++ type, N+ type, N type, and N− type is exemplary. Unless specifically mentioned, the resistance may be greater or smaller than that shown in this disclosure. The resistance relationship of each semiconductor layer of N++ type, N+ type, N type, and N-type may be reversed in some cases. Similarly, the resistance of each semiconductor layer of P++ type, P+ type, P type, and P-type is exemplary. Unless specifically mentioned, the resistance may be greater or smaller than that shown in this disclosure. The resistance relationship of each semiconductor layer of P++ type, P+ type, P type, and P− type may be reversed in some cases.

### Embodiment 1

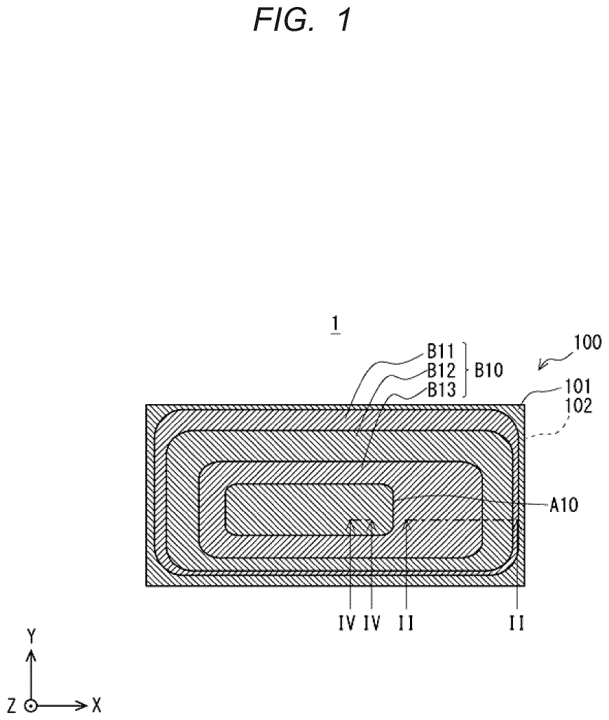

The semiconductor device according to Embodiment 1 will be described. FIG. 1 is a plan view illustrating the semiconductor device 1 according to Embodiment 1. As shown in FIG. 1, the semiconductor device 1 includes a semiconductor substrate 100. The semiconductor substrate 100 is, for example, a rectangular plate. The two plate surfaces of the semiconductor substrate 100 are referred to as the first main surface and the second main surface. The second main surface is the surface opposite the first main surface. Therefore, the semiconductor substrate 100 has a first main surface and a second main surface opposite the first main surface. For convenience of explanation, the first main surface may be referred to as the upper surface 101, and the second main surface as the lower surface 102.

Here, for convenience of explanation of the semiconductor device 1 and the like, an XYZ orthogonal coordinate system is introduced. The direction perpendicular to the upper surface 101 is the Z-axis direction, and the two directions perpendicular to the Z-axis direction are the X-axis direction and the Y-axis direction. The direction from the lower surface 102 to the upper surface 101 is the +Z-axis direction. The first main surface side is the +Z-axis direction side, which is the upper surface 101 side. The second main surface side is the −Z-axis direction side, which is the lower surface 102 side. For convenience, the +Z-axis direction is referred to as upward, and the −Z-axis direction as downward. Note that upward and downward are directions for convenience of explanation and do not indicate the direction when actually using the semiconductor device 1.

In this specification, “in plain view” means when viewed from a direction perpendicular to the upper surface 101 of the semiconductor substrate 100. In other words, “in plain view” means when the semiconductor substrate 100 is viewed from the +Z-axis direction in the −Z-axis direction.

In plain view, the semiconductor device 1 and the semiconductor substrate 100 include an element region A10 and a peripheral region B10. The element region A10 includes semiconductor elements. The peripheral region B10 is arranged to surround the element region A10. The peripheral region B10 may include the first peripheral region B11, the second peripheral region B12, and the third peripheral region B13. The third peripheral region B13 is arranged to surround the element region A10. The second peripheral region B12 is arranged to surround the element region A10 and the third peripheral region B13. Therefore, the third peripheral region B13 is disposed between the element region A10 and the second peripheral region B12. The first peripheral region B11 is arranged to surround element region A10, the third peripheral region B13, and the second peripheral region B12. Therefore, the second peripheral region B12 is disposed between the third peripheral region B13 and the first peripheral region B11.

The direction from the element region A10 towards the third peripheral region B13 is referred to as outward, and the direction from the third peripheral region B13 towards the element region A10 is referred to as inward. The peripheral region B10 is arranged outside the element region A10. The element region A10 is arranged inside the peripheral region B10. Below, the <peripheral region> and <element region> are described separately.

### <Peripheral Region>

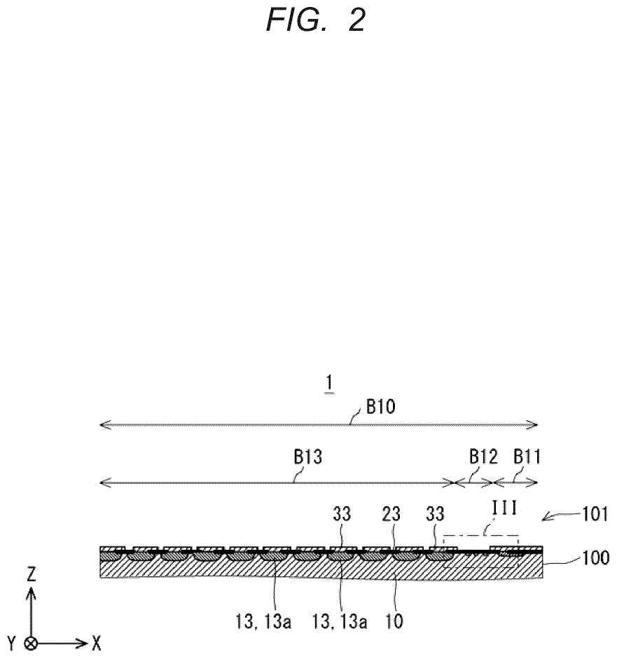

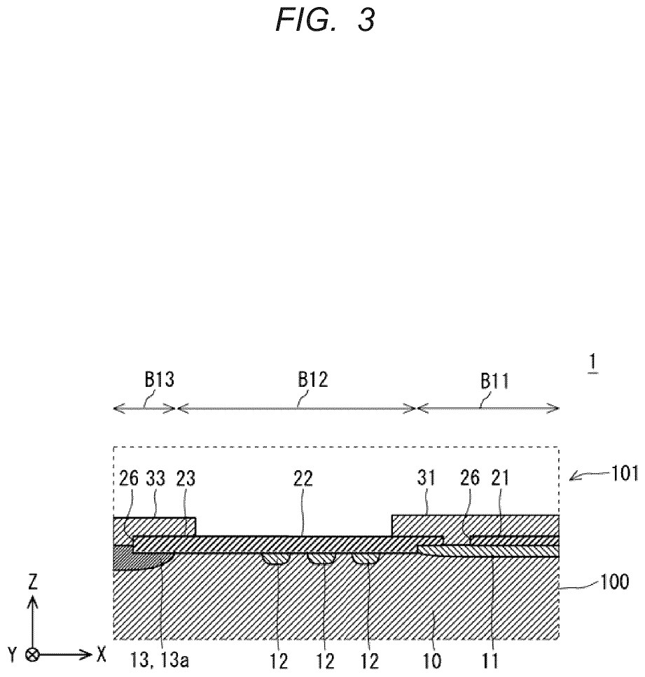

FIG. 2 is a cross-sectional view illustrating the peripheral region B10 in the semiconductor device 1 according to the first embodiment, showing the cross-section along line II-II of FIG. 1. FIG. 3 is an enlarged cross-sectional view illustrating the peripheral region B10 in the semiconductor device 1 according to the first embodiment, showing the cross-section of the III plane of FIG. 2. As shown in FIGS. 2 and 3, in the peripheral region B10, the first peripheral region B11, the second peripheral region B12, and the third peripheral region B13 are arranged in one direction from the element region A10 towards the third peripheral region B13. In FIGS. 2 and 3, the first peripheral region B11, the second peripheral region B12, and the third peripheral region B13 are arranged in the X-axis direction as an example. Note that the first peripheral region B11, the second peripheral region B12, and the third peripheral region B13 may be arranged in the Y-axis direction or in a direction inclined from the X-axis and Y-axis directions.

The semiconductor substrate 100 of the peripheral region B10 includes an N-type drift layer 10, an N++ type channel stop layer 11, and an N type guard ring layer 12. Note that the semiconductor substrate 100 of the peripheral region B10 may include a P type semiconductor layer 13. Additionally, the semiconductor substrate 100 of the peripheral region B10 may further include other semiconductor layers not shown.

The N-type drift layer 10 is included in the semiconductor substrate 100 of the peripheral region B10. That is, the N-type drift layer 10 is formed across the first peripheral region B11, the second peripheral region B12, and the third peripheral region B13. Note that the N-type drift layer 10 is also formed in the element region A10.

### <First Peripheral Region>

In the first peripheral region B11, the semiconductor device 1 includes a semiconductor substrate 100 containing the N-type drift layer 10. The N++ type channel stop layer 11 is arranged on the +Z-axis side relative to the N-type drift layer 10 in the semiconductor substrate 100 of the first peripheral region B11. The N++ type channel stop layer 11 has at least one annular shape surrounding the element region A10. Therefore, the element region A10 is arranged inside the area surrounded by the N++ type channel stop layer 11 in a plan view. In other words, the element region A10 is arranged inside the N++ type channel stop layer 11 in a plan view.

In the first peripheral region B11, the semiconductor device 1 may further include, in addition to the semiconductor substrate 100, a first interlayer insulating film 21 and an equipotential ring 31. The first interlayer insulating film 21 is provided on the +Z-axis side relative to the semiconductor substrate 100 where the N++ type channel stop layer 11 is arranged. The equipotential ring 31 is provided on the +Z-axis side relative to the first interlayer insulating film 21. The equipotential ring 31 includes conductive material. For example, the equipotential ring 31 contains aluminum. The equipotential ring 31 is connected to the N++ type channel stop layer 11 via a contact groove 26 formed in the first interlayer insulating film 21. The equipotential ring 31 may have a portion protruding inward relative to the N++ type channel stop layer 11. In the direction shown in the figure, the equipotential ring 31 may have a portion protruding in the −X-axis direction relative to the N++ type channel stop layer 11.

### <Second Peripheral Region>

In the second peripheral region B12, semiconductor device 1 includes a semiconductor substrate 100 containing the N-type drift layer 10. The N type guard ring layer 12 is arranged on the +Z-axis side relative to the N-type drift layer 10 in the semiconductor substrate 100 of the second peripheral region B12. The N type guard ring layer 12 is arranged inside the area surrounded by the N++ type channel stop layer 11. In other words, the N type guard ring layer 12 is arranged inside the N++ type channel stop layer 11 in a plan view. The N type guard ring layer 12 has at least one annular shape surrounding the element region A10.

The semiconductor substrate 100 in the peripheral region B12 may include multiple N type guard ring layers 12. The multiple N type guard ring layers 12 are arranged inside the area surrounded by the N++ type channel stop layer 11. In other words, the multiple N type guard ring layers 12 are arranged inside the N++ type channel stop layer 11 in a plan view. The multiple N type guard ring layers 12 are arranged annularly to surround the element region A10. The multiple N type guard ring layers 12 are spaced apart from each other. Additionally, the N type guard ring layer 12 is spaced apart from the N++ type channel stop layer 11. Furthermore, the N type guard ring layer 12 may be spaced apart from the equipotential ring 31 in a plan view. The N type guard ring layer 12 may be spaced apart from the P type semiconductor layer 13.

The concentration of N type impurities in the N-type guard ring layer 12 is greater than the concentration of N type impurities in the N-type drift layer 10 and less than the concentration of N type impurities in the N++ type channel stop layer 11. Additionally, if the semiconductor device 1 includes an IGBT as the semiconductor element in the element region A10, the N type guard ring layer 12 may contain the same type of impurities as the N type barrier layer in the IGBT. Furthermore, the N type guard ring layer 12 may contain the same concentration of impurities as the N type barrier layer. As will be described later, the N type barrier layer is a portion arranged below (collector side) the P type body layer (P type channel layer) adjacent to the trench gate electrode.

In the second peripheral region B12, the semiconductor device 1 may further include, in addition to the semiconductor substrate 100, a second interlayer insulating film 22. The second interlayer insulating film 22 is provided on the +Z-axis side relative to the semiconductor substrate 100 where the N type guard ring layer 12 is arranged. The thickness of the second interlayer insulating film 22 is greater than the thickness of the first interlayer insulating film 21. For example, the second interlayer insulating film 22 may include insulating materials such as LOCOS (Local Oxidation of Silicon). The N type guard ring layer 12 may be covered by LOCOS. In contrast, the first interlayer insulating film 21 may be formed by a different process than the second interlayer insulating film 22.

### <Third Peripheral Region>

In the third peripheral region B13, semiconductor device 1 includes a semiconductor substrate 100 containing the N-type drift layer 10. In the third peripheral region B13, the semiconductor substrate 100 may include at least one P type semiconductor layer 13. The P type semiconductor layer 13 is arranged on the +Z-axis side relative to the N-type drift layer 10 in the semiconductor substrate 100 of the third peripheral region B13. The P type semiconductor layer 13 is arranged inside the area surrounded by the N++ type channel stop layer 11 in a plan view. In other words, the P type semiconductor layer 13 is arranged inside the N++ type channel stop layer 11 in a plan view. The P type semiconductor layer 13 may be arranged annularly to surround the element region A10.

In the third peripheral region B13, the semiconductor device 1 may further include, in addition to the semiconductor substrate 100, a third interlayer insulating film 23 and at least one field plate 33. The third interlayer insulating film 23 is provided on the +Z-axis side relative to the semiconductor substrate 100 where the P type semiconductor layer 13 is arranged. The thickness of the third interlayer insulating film 23 may be greater than the thickness of the first interlayer insulating film 21.

Field plate 33 is arranged on the +Z-axis side relative to the third interlayer insulating film 23. Field plate 33 includes conductive material. For example, the conductive material contains aluminum. Field plate 33 is arranged inside the area surrounded by the N++ type channel stop layer 11 in a plan view. In other words, field plate 33 is arranged inside the N++ type channel stop layer 11 in a plan view. Field plate 33 is arranged annularly to surround the element region A10. The field plate 33 may be connected to the P type semiconductor layer 13 via contact groove 26 formed in the third interlayer insulating film 23. The field plate 33 may have a portion protruding outward relative to the P type semiconductor layer 13. In the direction shown in the figure, the field plate 33 may have a portion protruding in the +X-axis direction relative to the P type semiconductor layer 13.

Semiconductor device 1 may include an outermost peripheral structure. The outermost peripheral structure includes at least one of the P type semiconductor layers 13 and the field plate 33, which are arranged at the outermost position inside the area surrounded by the N++ type channel stop layer 11 in a plan view. In that case, the N type guard ring layer 12 is disposed between the outermost structure within the interior surrounded by the N++ type channel stop layer 11 and the N++ type channel stop layer 11 in plain view.

The semiconductor substrate 100 may include a P type semiconductor layer 13, which may contain multiple field-limiting ring layers 13a. The multiple field-limiting ring layers 13a are positioned on the +Z axis side relative to the N-type drift layer 10. In plain view, the multiple field-limiting ring layers 13a are located within the interior surrounded by the N++ type channel stop layer 11. That is, in plain view, the multiple field-limiting ring layers 13a are positioned inside the N++ type channel stop layer 11. The multiple field-limiting ring layers 13a are arranged annularly to surround the element region A10. The multiple field-limiting ring layers 13a are spaced apart from each other.

The semiconductor device 1 may be equipped with multiple field plates 33 corresponding to the multiple field-limiting ring layers 13a. The multiple field plates 33 may be connected to the multiple field-limiting ring layers 13a through multiple contact grooves 26 formed in the third interlayer insulating film 23. In this case, the outermost structure includes either the field-limiting ring layer 13a or the field plate 33 positioned at the outermost periphery among the multiple field-limiting ring layers 13a and multiple field plates 33. Therefore, the N type guard ring layer 12 is disposed between either the field-limiting ring layer 13a or the field plate 33 positioned at the outermost periphery within the interior surrounded by the N++ type channel stop layer 11 and the N++ type channel stop layer 11 in plain view.

In cases where the semiconductor element in the element region A10 includes a P type semiconductor layer 13 such as a P type floating layer positioned on the +Z axis side relative to the N-type drift layer 10, the P type semiconductor layer 13 may function as the outermost structure. In such cases, the semiconductor substrates 100 in the peripheral region B10, including the third peripheral region B13, does not have to have the P type semiconductor layer 13. The N type guard ring layer 12 is disposed between the P type semiconductor layer 13 in the element region A10 and the N++ type channel stop layer 11.

Additionally, for example, in a structure like the JTE (Junction Termination Extension), the semiconductor substrate 100 in the peripheral region B10 may include a P type semiconductor layer 13 functioning as a termination structure positioned on the +Z axis side relative to the N-type drift layer 10. The P type semiconductor layer 13 may be positioned within the interior surrounded by the N++ type channel stop layer 11 in plain view. In this case, the outermost structure includes the P type semiconductor layer 13.

In the peripheral region B10, the interlayer insulating film, including the first interlayer insulating film 21, the second interlayer insulating film 22, and the third interlayer insulating film 23, is provided on the +Z axis side relative to the semiconductor substrate 100 in the peripheral region B10. At least one of the first interlayer insulating film 21, the second interlayer insulating film 22, and the third interlayer insulating film 23 may have fixed positive charges. Thus, the interlayer insulating film in the peripheral region B10 may have fixed positive charges. For example, at least one of the first interlayer insulation films 21, the second interlayer insulating film 22, and the third interlayer insulation film 23 may be formed using P-TEOS deposited by a plasma CVD method with TEOS (Tetra Ethoxy Silane) as the main raw material. During this process, the charges generated within the P-TEOS may be fixed by RTA (Rapid Thermal Anneal).

### <Element Region>

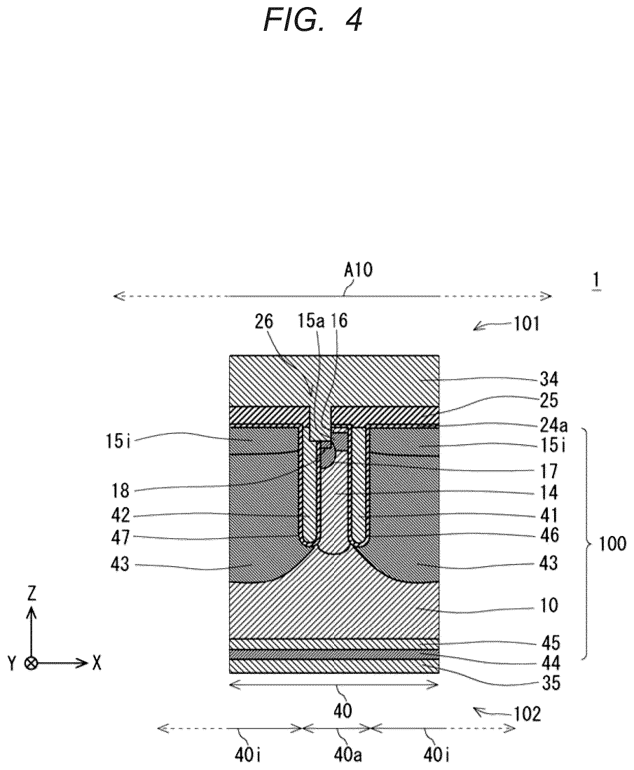

FIG. 4 is a cross-sectional view illustrating the element region A10 in the semiconductor device 1 according to the first embodiment, showing the cross-section along line IV-IV in FIG. 1. As shown in FIG. 4, in element region A10, the semiconductor device 1 may further include an insulating film 24a, an interlayer insulating film 25, an emitter wiring 34, and a collector wiring 35, in addition to the semiconductor substrate 100. Multiple semiconductor elements may be formed in element region A10. The semiconductor elements may include, for example, IGBT. The semiconductor elements may also include at least one of MOSFET and diode.

The semiconductor substrate 100 in the element region A10 includes, as part of the IGBT configuration, an N-type drift layer 10, an N type barrier layer 14, P type body layers 15a and 15i, an N+ type emitter layer 16, a P+ type latch-up prevention layer 17, and a P+ type body contact layer 18. Additionally, the semiconductor substrate 100 in the element region A10 includes a trench gate electrode 41, a trench emitter electrode 42, a P type floating layer 43, a P+ type collector layer 44, an N type field stop layer 45, a trench insulating film 46, and a trench insulating film 47. The emitter wiring 34 is connected to the N+ type emitter layer 16, the P type body layer 15a, the P+ type body contact layer 18, and the trench emitter electrode 42 through contact grooves 26 formed in the insulating film 24a and the interlayer insulating film 25. The collector wiring 35 is connected to the P+ type collector layer 44.

The N-type drift layer 10 is continuously disposed across the element region A10 and the peripheral region B10. In the element region A10, the N-type drift layer 10 is positioned on the +Z axis side relative to the N type field stop layer 45 in the semiconductor substrate 100.

The N type barrier layer 14 is positioned on the +Z axis side relative to the N-type drift layer 10. In plan view, the N type barrier layer 14 extends, for example, in the Y-axis direction. The N type barrier layer 14 is sandwiched between the trench gate electrode 41 and the trench emitter electrode 42 from both sides in the X-axis direction. That is, the N type barrier layer 14 is positioned within the interior sandwiched by the trench gate electrode 41 and the trench emitter electrode 42.

The portion P type body layer 15a of the P type body layer present in the active cell region 40a is positioned on the +Z axis side relative to the N type barrier layer 14. The P type body layer 15a is sandwiched between the trench gate electrode 41 and the trench emitter electrode 42 from both sides in the X-axis direction. The P type body layer 15a is connected to the emitter wiring 34 filled in the contact groove 26 penetrating the interlayer insulating film 25, the insulating film 24a, and the N+ type emitter layer 16.

The N+ type emitter layer 16 is positioned on the +Z axis side relative to the P type body layer 15a. The N+ type emitter layer 16 is positioned within the interior sandwiched by the trench gate electrode 41 and the trench emitter electrode 42. The N+ type emitter layer 16 is connected to the emitter wiring 34 filled in the contact groove 26 penetrating the insulating film 24a and the interlayer insulating film 25.

The trench gate electrode 41 and the trench emitter electrode 42 are provided to sandwich the N type barrier layer 14, the P type body layer 15a, and the N+ type emitter layer 16 from both sides in the X-axis direction. In plan view, the trench gate electrode 41 and the trench emitter electrode 42 include portions extending, for example, in the Y-axis direction. For example, the trench gate electrode 41 is positioned on the +X axis side relative to the trench emitter electrode 42. The trench emitter electrode 42 is positioned on the −X axis side relative to the trench gate electrode 41.

The trench gate electrode 41 is connected to the gate wiring, for example. The trench emitter electrode 42 is connected to the emitter wiring 34 filled in the contact groove 26 penetrating the insulating film 24a and the interlayer insulating film 25. Thus, the N+ type emitter layer 16, the P type body layer 15a, and the trench gate electrode 41 are connected to the emitter wiring 34. The structure between the trench gate electrode 41 and the trench emitter electrode 42 is called the trench inter-structure. For example, the trench inter-structure of the IGBT includes the N type barrier layer 14, the P type body layer 15a, and the N+ type emitter layer 16. The trench inter-structure of the IGBT may further include the P+ type latch-up prevention layer 17 and the P+ type body contact layer 18. For example,

The P type floating layer 43 is provided between adjacent IGBTs in multiple IGBTs. For example, the P type floating layer 43 is provided between the trench gate electrode 41 of the IGBT on the −X axis side and the trench emitter electrode 42 of the IGBT on the +X axis side among adjacent IGBTs. The P type floating layer 43 is provided on the opposite side of the N type barrier layer 14, the P type body layer 15a, and the N+ type emitter layer 16, sandwiching the trench gate electrode 41 or the trench emitter electrode 42.

The P type floating layer 43 is positioned on the +Z axis side relative to the N-type drift layer 10. The P type body layer 15i is positioned on the +Z axis side relative to the P type floating layer 43. Thus, on the +Z axis side of the N-type drift layer 10, from the −X axis side along the X-axis direction, a stack of the P type floating layer 43 and the P type body layer 15i, the trench emitter electrode 42 (covered by the trench insulating film 47), the trench inter-structure, the trench gate electrode 41 (covered by the trench insulating film 46), and a stack of the P type floating layer 43 and the P type body layer 15i are arranged. In the element region A10, such a configuration is arranged to repeat in the X-axis direction.

Multiple IGBTs are formed in the element region A10. The IGBT at the +X-axis end of the element region A10 and the IGBT at the −X-axis end of the element region A10, except for these, the P type floating layer 43 is in contact with the trench gate electrode 41 and the trench emitter electrode 42. In other words, the P type floating layer 43 is formed between adjacent IGBTs except at the X-axis ends of the element region A10.

If the third peripheral region B13 in the peripheral region B10 does not have a P type semiconductor layer 13 such as a field limiting ring layer 13a, the P type floating layer 43 of the element region A10 may function as the P type semiconductor layer 13 of the outermost peripheral structure. That is, the outermost peripheral structure includes the P type floating layer 43. Therefore, the P type floating layer 43 of the IGBT arranged at the outermost periphery of the element region A10 may be the annular P type semiconductor layer 13 arranged on the +Z-axis side of the N− type drift layer 10 within the N++ type channel stop layer 11. Thus, the N type guard ring layer 12 may be arranged between the annular P type floating layer 43 of the outermost periphery and the N++ type channel stop layer 11. In this way, the P type semiconductor layer 13 may include the P type floating layer 43.

The trench insulating film 46 is provided between the trench emitter electrode 42 and the semiconductor substrate 100. Specifically, the trench insulating film 46 is provided between the trench emitter electrode 42 and the N− type drift layer 10, N type barrier layer 14, P type body layer 15a, N+ type emitter layer 16, P type body layer 15i, and P type floating layer 43. The trench insulating film 47 is provided between the trench gate electrode 41 and the semiconductor substrate 100. Specifically, the trench insulating film 47 is provided between the trench gate electrode 41 and the N− type drift layer 10, N type barrier layer 14, P type body layer 15a, P type body layer 15i, and P type floating layer 43.

The N type field stop layer 45 is arranged on the −Z-axis side of the N− type drift layer 10. The P+ type collector layer 44 is arranged on the −Z-axis side of the N type field stop layer 45. The P+ type collector layer 44 is connected to the collector wiring 35.

The element region A10 may include a plurality of active cell regions 40a and a plurality of inactive cell regions 40i. The plurality of active cell regions 40a extend in the Y-axis direction in a plan view and are periodically arranged in the X-axis direction. In other words, the active cell regions 40a are formed in a vertical stripe shape.

Also, the plurality of inactive cell regions 40i extend in the Y-axis direction in a plan view and are periodically arranged in the X-axis direction. The active cell regions 40a and the inactive cell regions 40i are alternately arranged in the X-axis direction. A unit cell region 40 is constituted by one active cell region 40a, half of the inactive cell region 40i adjacent to the +X-axis side of the active cell region 40a, and half of the inactive cell region 40i adjacent to the −X-axis side of the active cell region 40a. Therefore, the element region A10 includes a plurality of unit cell regions 40. The unit cell region 40 includes, for example, an IGBT as a semiconductor element. Therefore, the element region A10 may include a plurality of IGBTs.

In the active cell region 40a, on the N− type drift layer 10, in order from the bottom, in addition to the N type barrier layer 14, P type body layer 15a, and N+ type emitter layer 16, a P+ type latch-up prevention layer 17 and a P+ type body contact layer 18 may be arranged. The N+ type emitter layer 16 may be provided only on the trench gate electrode 41 side. On the +Z-axis side of the trench gate electrode 41, trench emitter electrode 42, P type body layer 15a, and N+ type emitter layer 16, an insulating film 24a and an interlayer insulating film 25 are formed. In active cell region 40a, a contact groove 26 reaching the trench emitter electrode 42 and the inside of the semiconductor substrate 100 is formed in part of the insulating film 24a and the interlayer insulating film 25. In the bottom of this contact groove 26, a P+ type body contact layer 18 and a P+ type latch-up prevention layer 17 are provided. Through this contact groove 26, the P type body layer 15a and the N+ type emitter layer 16 are connected to the emitter wiring 34 provided on the insulating film 24a and the interlayer insulating film 25.

Here, the N type barrier layer 14 is a barrier region to prevent holes from flowing into the passage from the N− type drift layer 10 to the N+ type emitter layer 16. The impurity concentration of the N type barrier layer 14 is lower than that of the N+ type emitter layer 16 and higher than that of the N-type drift layer 10. The presence of this N type barrier layer 14 effectively prevents holes accumulated in the N− type drift layer 10 from entering the emitter passage (the passage from the N− type drift layer 10 to the P+ type body contact layer 18) of the active cell region 40a.

In contrast, in inactive cell region 40i, the P type floating layer 43 and the P type body layer 15i are arranged on the N− type drift layer 10 in order from the bottom. The depth of the P type floating layer 43 is deeper than the depth of the trench gate electrode 41 and the trench emitter electrode 42. Also, the P type floating layer 43 is distributed to cover the lower ends of the trench gate electrode 41 and the trench emitter electrode 42.

### <Manufacturing Method of the Semiconductor Device>

Next, the manufacturing method of the semiconductor device 1 of this embodiment will be described. First, a semiconductor substrate 100 including a silicon single crystal into which an N type impurity such as phosphorus is introduced is prepared. The semiconductor substrate 100 has an upper surface 101 as the first main surface and a lower surface 102 as the second main surface opposite to the upper surface 101. Then, in a plan view, an element region A10 and a peripheral region B10 surrounding the element region A10 are set on the semiconductor substrate 100. In the step of setting element region A10 and the peripheral region B10, the peripheral region B10 may include a third peripheral region B13 surrounding the element region A10, a second peripheral region B12 surrounding the element region A10 and the third peripheral region B13, and a first peripheral region B11 surrounding the element region A10, the third peripheral region B13, and the second peripheral region B12.

An element isolation member such as LOCOS may be formed on the semiconductor substrate 100. For example, LOCOS may be formed as the second interlayer insulating film 22 or a part thereof on the +Z-axis side of the semiconductor substrate 100 in the second peripheral region B12. Hereinafter, the <Manufacturing method of the peripheral region> and the <Manufacturing method of the element region> will be described.

### <Manufacturing Method of the Peripheral Region>

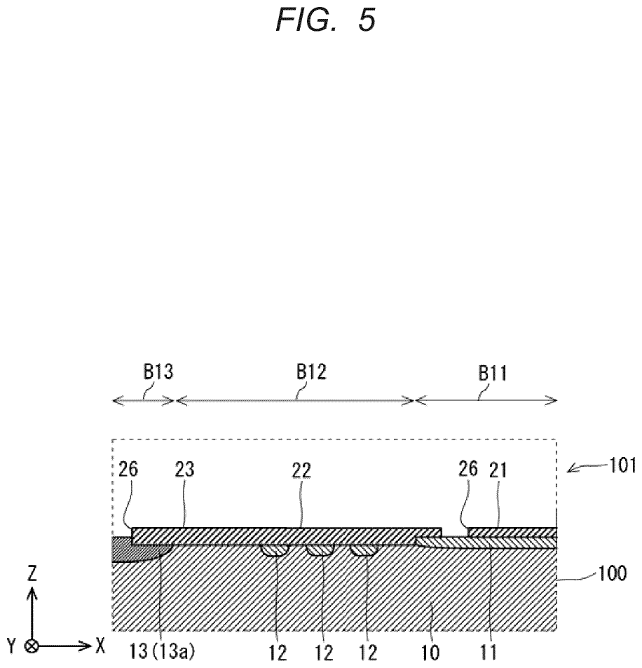

FIG. 5 is a cross-sectional view illustrating the manufacturing process of the peripheral region B10 in the manufacturing method of the semiconductor device 1 according to the first embodiment. As shown in FIG. 5, an N− type drift layer 10 and an N++ type channel stop layer 11 arranged on the +Z-axis side of the N− type drift layer 10 are formed on the semiconductor substrate 100 in the first peripheral region B11. The N++ type channel stop layer 11 is formed in an annular shape to surround the element region A10. For example, by introducing an N type impurity with a higher concentration than the N− type drift layer 10 into the semiconductor substrate 100, the N++ type channel stop layer 11 is formed on the N− type drift layer 10.

Also, an N− type drift layer 10 and an N type guard ring layer 12 arranged on the +Z-axis side of the N− type drift layer 10 are formed on the semiconductor substrate 100 in the second peripheral region B12. The N type guard ring layer 12 is formed to have at least one annular shape arranged between the outermost peripheral structure inside the N++ type channel stop layer 11 and the N++ type channel stop layer 11. For example, by introducing an N type impurity with a higher concentration than the N− type drift layer 10 into the semiconductor substrate 100, the N type guard ring layer 12 is formed on the N− type drift layer 10.

In the step of forming the N type guard ring layer 12, the concentration of the N type impurity in the N type guard ring layer 12 is made larger than the concentration of the N type impurity in the N-type drift layer 10. Also, the concentration of the N type impurity in the N type guard ring layer 12 is made smaller than the concentration of the N type impurity in the N++ type channel stop layer 11. Note that the step of forming the N type guard ring layer 12 may introduce an N type impurity into the semiconductor substrate 100 through the second interlayer insulating film 22 or a part thereof, such as LOCOS. For example, an N type impurity may be introduced into the semiconductor substrate 100 by an ion implantation method.

Also, the outermost peripheral structure may be formed in the third peripheral region B13. The outermost peripheral structure includes at least one of a field plate 33 containing a conductive material arranged on the +Z-axis side of the semiconductor substrate 100 and a P type semiconductor layer 13 arranged on the +Z-axis side of the N− type drift layer 10 in the semiconductor substrate 100.

Form the first interlayer insulating film 21 on the +Z axis side of the semiconductor substrate 100 in the first peripheral region B11. As described above, form the second interlayer insulating film 22 on the +Z axis side of the semiconductor substrate 100 in the second peripheral region B12. In the process of forming the first interlayer insulating film 21 or the second interlayer insulating film 22, make the thickness of the second interlayer insulating film 22 greater than that of the first interlayer insulating film 21. For example, form the portion of the second interlayer insulating film 22 on the side of the semiconductor substrate 100 using LOCOS, and after performing ion implantation to form the N type guard ring layer 12 and the N++ type channel stop layer 11, form the remaining portion of the second interlayer insulating film 22 and the first interlayer insulating film 21 using P-TEOS in the same process. Form the third interlayer insulating film 23 on the +Z axis side of the semiconductor substrate 100 in the third peripheral region B13. The portion of the third interlayer insulating film 23 on the side of the semiconductor substrate 100 may be formed using LOCOS in the same process as the similar portion of the second interlayer insulating film 22. The remaining portion of the third interlayer insulating film 23 may be formed using P-TEOS in the same process as the first interlayer insulating film 21. Alternatively, the entire third interlayer insulating film 23 may be formed using P-TEOS in the same process as the first interlayer insulating film 21. Form contacts groove 26 in the first interlayer insulating film 21 and the third interlayer insulation film 23.

Then, as shown in FIGS. 2 and 3, fill the contact grooves 26 in the first peripheral region B11 and form an equipotential ring 31 on the first interlayer insulating film 21 in the first peripheral region B11. Also, fill the contact grooves 26 in the third peripheral region B12 and form a field plate 33 on the third interlayer insulating film 23 in the third peripheral region B13. In this way, the peripheral region B10 of the semiconductor device 1 can be formed.

### <Manufacturing Method of the Element Region>

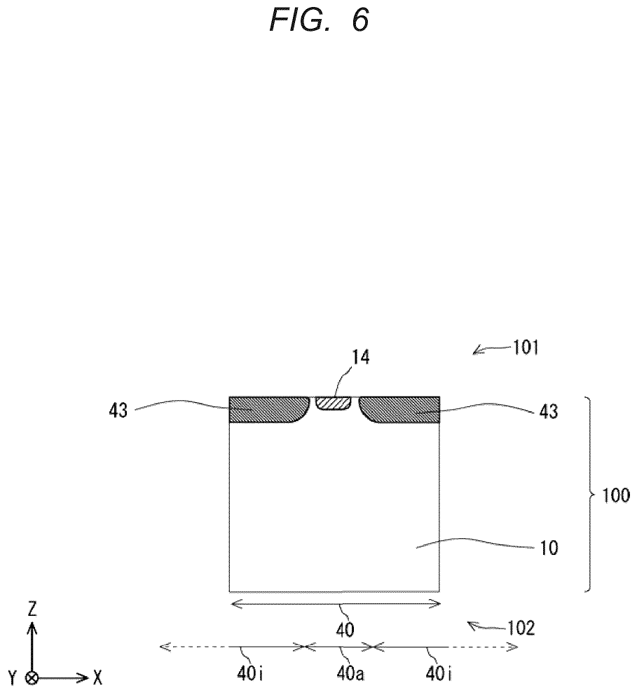

Next, the manufacturing method of the element region A10 will be described. The manufacturing method of element region A10 includes a step of forming an IGBT as a semiconductor element in the element region A10. The manufacturing method of element region A10 and the manufacturing method of peripheral region B10 may include manufacturing processes that are carried out simultaneously. FIGS. 6 to 10 are cross-sectional views illustrating the manufacturing process of the element region A10 in the manufacturing method of the semiconductor device 1 according to the first embodiment.

As shown in FIG. 6, for example, by introducing N type impurities into the upper surface 101 side of the semiconductor substrate 100 using an ion implantation method with a resist pattern as a mask, form the N type barrier layer 14. The N type barrier layer 14 is formed in the active cell region 40a. As described above, the element region A10 has multiple active cell regions 40a and multiple inactive cell regions 40i. In the step of forming the N type guard ring layer 12 in the manufacturing method of the peripheral region B10 described above, the N type guard ring layer 12 may be formed simultaneously with the N type barrier layer 14 in the process of forming the IGBT.

Next, for example, by introducing P type impurities into the upper surface 101 side of the semiconductor substrate 100 using an ion implantation method with a resist pattern as a mask, form the P type floating layer 43. The P type floating layer 43 is formed in inactive cell region 40i. In the step of forming the P type semiconductor layer 13 in the manufacturing method of the peripheral region B10 described above, the P type semiconductor layer 13 may be formed simultaneously with the P type floating layer 43 in the process of forming the IGBT.

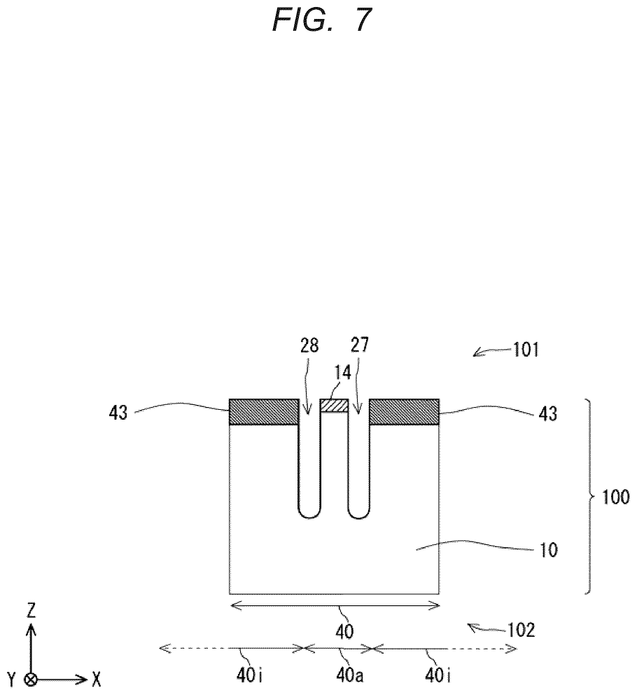

Next, as shown in FIG. 7, for example, using a hard mask made of a silicon oxide film, form multiple trenches 27 and multiple trenches 28 on the upper surface 101 of the semiconductor substrate 100 by anisotropic dry etching.

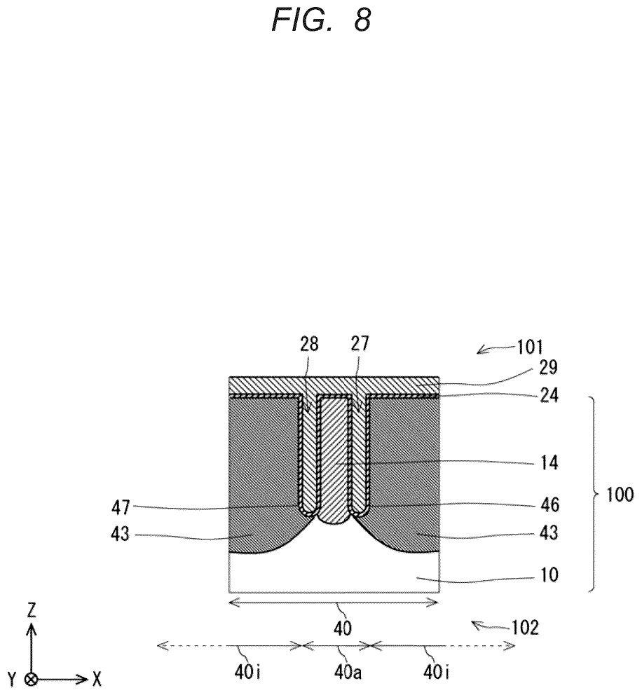

Next, as shown in FIG. 8, perform lateral diffusion for the P type floating layer 43 and the N type barrier layer 14. At this time, perform the lateral diffusion so that the −Z axis side end of the P type floating layer 43 is positioned at the −Z axis side end of the multiple trenches 27 and multiple trenches 28 in the Z-axis direction. Next, for example, form an insulating film 24 made of a silicon oxide film on the upper surface 101 of the semiconductor substrate 100 by thermal oxidation or other methods. Also, form a trench insulating film 46 made of a silicon oxide film on the inner wall of the trench 27. Furthermore, form a trench insulating film 47 made of a silicon oxide film on the inner wall of the trench 28. The insulating film 24, trench insulating film 46, and trench insulating film 47 may be formed simultaneously.

By the aforementioned lateral diffusion, form the P type floating layer 43 on the +X axis side of the trench 27 and the −X axis side of the trench 28. Preferably, the P type floating layer 43 contacts the trench insulating film 46 formed on the inner wall of trench 27 and the trench insulating film 47 formed on the inner wall of trench 28. Also, form the N type barrier layer 14 between the −X axis side of the trench 27 and the +X axis side of the trench 28. Preferably, the N type barrier layer 14 contacts the trench insulating film 46 formed on the inner wall of the trench 27 and the trench insulating film 47 formed on the inner wall of the trench 28. During the lateral diffusion, the region of the N type semiconductor substrate 100 where the P type floating layer 43 and the N type barrier layer 14 are not formed becomes the N− type drift layer 10.

Next, on the upper surface 101 of the semiconductor substrate 100, and inside the trench 27 and trench 28, form a conductive film 29 composed of a doped poly-silicon film doped with phosphorus, for example, by CVD (Chemical Vapor Deposition) or other methods.

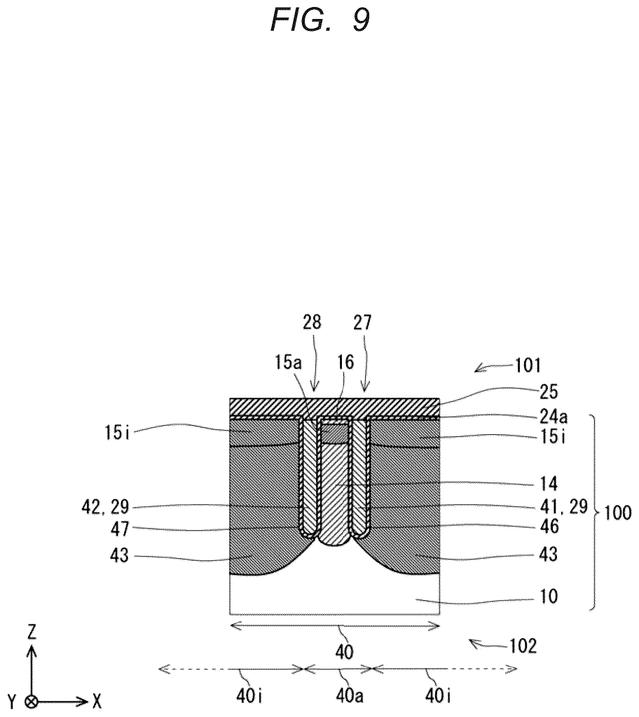

Next, as shown in FIG. 9, for example, etch back the conductive film 29 by dry etching. This forms a trench gate electrode 41 composed of the conductive film 29 embedded via the trench insulating film 46 inside the trench 27. Also, form a trench emitter electrode 42 composed of the conductive film 29 embedded via the trench insulating film 47 inside the trench 28.

Next, for example, remove the insulation film 24 outside the trenches 27 and 28 by dry etching. Next, for example, form an insulating film 24a composed of a relatively thin silicon oxide film for subsequent ion implantation on the upper surface 101 of the semiconductor substrate 100 by thermal oxidation or CVD. The insulating film 24a is also called an ion implantation through insulating film as it is used as a through film for ion implantation. Next, by introducing P type impurities into the entire surface of the element region A10 and other necessary parts using an ion implantation method with a resist pattern as a mask, form the P type body layers 15a and 15i.

Specifically, in active cell region 40a, form the P type body layer 15a in contact with the trench insulating film 46 formed on the inner wall of the trench 27 and the trench insulating film 47 formed on the inner wall of the trench 28 between the trench 27 and trench 28. This P type body layer 15a is formed on the N type barrier layer 14. Also, in the inactive cell region 40i, this P type body layer 15i is formed on the P type floating layer 43.

Furthermore, for example, by introducing N type impurities into the upper layer of the P type body layer 15a in the active cell region 40a using an ion implantation method with a resist pattern as a mask, form the N+ type emitter layer 16. In the step of forming the N++ type channel stop layer 11 in the manufacturing method of the peripheral region B10 described above, the N++ type channel stop layer 11 may be formed simultaneously with the N+ type emitter layer 16 in the process of forming the IGBT. Next, on the upper surface 101 of the semiconductor substrate 100, for example, by CVD or other methods, form an interlayer insulating film 25 including, for example, a PSG (Phosphorous Silicate Glass) film. The interlayer insulating film 25 is formed to cover the P type body layers 15a and 15i via the insulating film 24a in each of the active cell region 40a and the inactive cell region 40i. As materials for the interlayer insulating film 25, in addition to the PSG film, BPSG (Borophosphosilicate Glass) film, NSG (Non-doped Silicate Glass) film, SOG (Spin-On-Glass) film, P-TEOS film, or composite films of these can be suitably exemplified. In the step of forming the first interlayer insulating film 21 in the manufacturing method of the peripheral region B10 described above, the first interlayer insulating film 21 may be formed simultaneously with the interlayer insulating film 25 in the process of forming the IGBT.

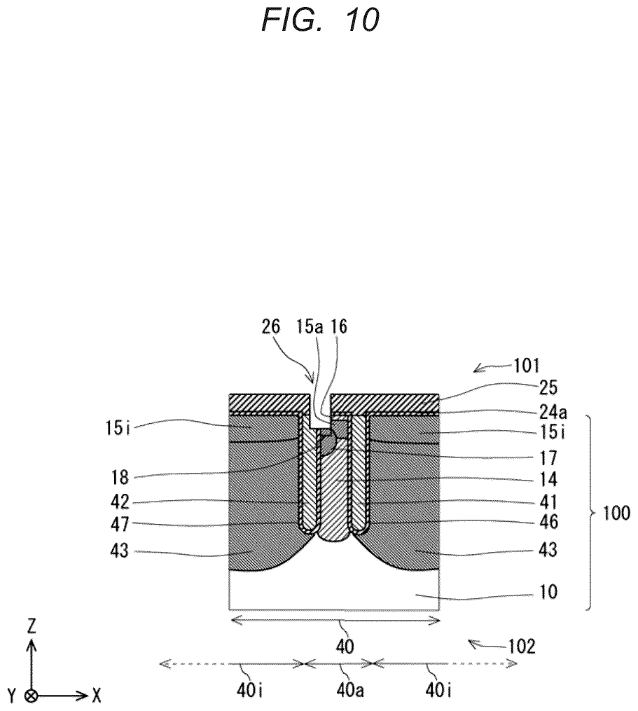

Next, as shown in FIG. 10, form contact grooves 26 in the interlayer insulating film 25 and the insulating film 24a by anisotropic dry etching using a resist pattern as a mask. Subsequently, extend the contact grooves 26 into the semiconductor substrate 100 by anisotropic dry etching. This forms the contact grooves 26 as openings that penetrate the interlayer insulating film 25, insulating film 24a, and N+ type emitter layer 16 to reach the P type body layer 15a and partway through the trench 28 in the active cell region 40a. In the active cell region 40a, the contact grooves 26 are continuously formed along the Y-axis direction in a plan view.

Next, for example, through the contact groove 26, P type impurities are ion-implanted to form the P+ type body contact layer 18. Next, for example, through the contact groove 26, P type impurities are ion-implanted to form the P+ type latch-up prevention layer 17. The concentration of P type impurities in the P+ type body contact layer 18 is higher than that in the P+ type latch-up prevention layer 17.

Thus, in the active cell region 40a, the P+ type body contact layer 18 and the P+ type latch-up prevention layer 17 are formed in the portion of the P type body layer 15a exposed through the contact groove 26. In active cell region 40a, the P+ type body contact layer 18 and the P+ type latch-up prevention layer 17 are continuously formed along the Y-axis direction in plain view. That is, the P+ type body contact layer 18 and the P+ type latch-up prevention layer 17 are formed in the portion located between the trench 27 and the trench 28, in contact with the P type body layer 15a. In active cell region 40a, the concentration of P type impurities in the P+ type body contact layer 18 and the P+ type latch-up prevention layer 17 is higher than that in the P type body layer 15a.

Next, as shown in FIG. 4, emitter wiring 34 is formed. Specifically, for example, by sputtering, a titanium-tungsten film is formed as a barrier metal film on the upper surface 101 of the semiconductor substrate 100. Then, on the entire surface of the barrier metal film, an aluminum metal film is formed by sputtering to embed the contact groove 26. As a result, in the active cell region 40a, emitter wiring 34 is formed inside the contact groove 26 and on the interlayer insulating film 25. The emitter wiring 34 electrically connects multiple N+ type emitter layers 16, multiple P+ type body contact layers 18, and multiple P+ type latch-up prevention layers 17 formed in the active cell region 40a.

Next, back grinding is performed on the lower surface 102 of the semiconductor substrate 100. This thins the semiconductor substrate 100. Next, N type impurities are introduced into the lower surface 102 of the semiconductor substrate 100 by ion implantation to form the N type field stop layer 45. Then, P type impurities are introduced into the lower surface 102 of the semiconductor substrate 100 by ion implantation to form the P+ type collector layer 44. Next, for example, by sputtering, collector wiring 35 electrically connected to the P+ type collector layer 44 is formed on the lower surface 102 of the semiconductor substrate 100. In this way, the element region A10 can be formed.

Afterward, the semiconductor substrate 100 is divided into chip regions by dicing etc., and the semiconductor device 1 is nearly completed by sealing it in a package as needed.

Next, the effects of this embodiment will be explained. The semiconductor device 1 of this embodiment includes at least one annular N type guard ring layer 12 between the outermost peripheral structure and the N++ type channel stop layer 11 within the interior surrounded by the N++ type channel stop layer 11. This allows the size of the peripheral breakdown voltage structure in the semiconductor device 1 to be reduced without compromising the negative charge tolerance.

For example, a large amount of negative charge may reach the upper surface 101 side of the semiconductor substrate 100 while using the semiconductor device 1. In such cases, the vicinity of the upper surface 101 directly below the second interlayer insulating film 22 in the second peripheral region B12 may become inverted or close to inversion, making it difficult to maintain breakdown voltage. However, semiconductor device 1 of this embodiment has an N type guard ring layer 12 directly below the upper surface 101 of the second interlayer insulating film 22. Therefore, it is possible to suppress the inversion of the vicinity of the upper surface 101 directly below the second interlayer insulating film 22.

Thus, to suppress inversion due to negative charge on the upper surface 101 of the semiconductor substrate 100, it is effective to increase the donor density of the upper surface 101 of the semiconductor substrate 100. One reason is that the negative charge on the upper surface 101 of the semiconductor substrate 100 can be neutralized by the positive charge of ionized donors. Here, the concentration of N type impurities in the N type guard ring layer 12 is greater than the concentration of N type impurities in the N− type drift layer 10 and less than the concentration of N type impurities in the N++ type channel stop layer 11. It is important to have such a concentration of N type impurities in the N type guard ring layer 12 to increase the donor density of the upper surface 101 of the semiconductor substrate 100 in the second peripheral region B12. Therefore, it is possible to suppress inversion near the upper surface 101.

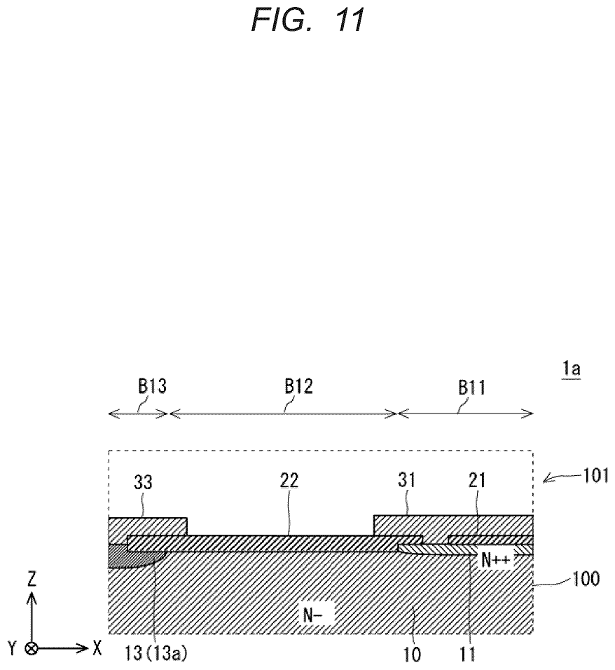

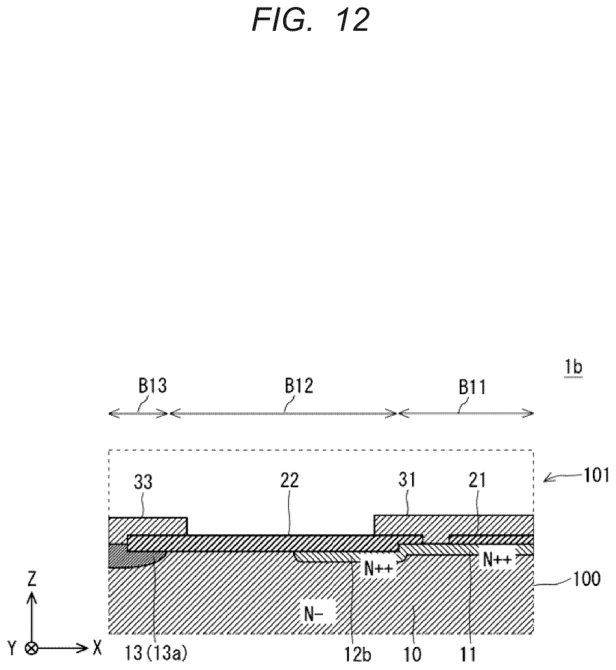

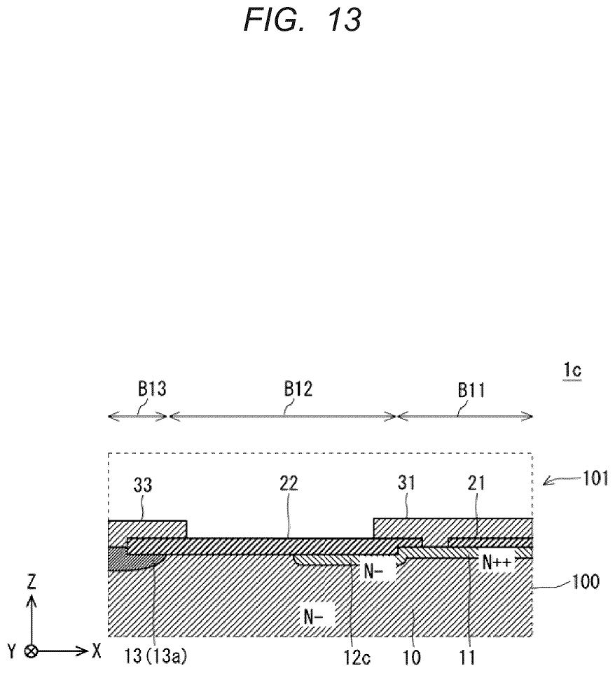

FIG. 11 is a cross-sectional view illustrating the peripheral region B10 in the semiconductor device 1a according to Comparative Example 1. FIG. 12 is a cross-sectional view illustrating the peripheral region B10 in the semiconductor device 1b according to Comparative Example 2. FIG. 13 is a cross-sectional view illustrating the peripheral region B10 in the semiconductor device 1c according to Comparative Example 3.

As shown in FIG. 11, the semiconductor device 1a of Comparative Example 1 does not have an N type guard ring layer 12 on the N− type drift layer 10 in the second peripheral region B12. In this case, when a large amount of negative charge reaches the upper surface 101 side of the semiconductor substrate 100 during use of the semiconductor device 1a, the vicinity of the upper surface 101 directly below the second interlayer insulating film 22 may become inverted or close to inversion, making it difficult to maintain breakdown voltage.

As shown in FIG. 12, the semiconductor device 1b of Comparative Example 2 has a semiconductor layer 12b containing N++ type impurities of the same concentration as the N++ type channel stop layer 11 on the N− type drift layer 10 in the second peripheral region B12. In this case, the donor density does not continuously deplete from the semiconductor layer 12b to the N++ type channel stop layer 11. Consequently, the end of the semiconductor layer 12b on the −X axis side becomes the same potential as the equipotential ring 31. In other words, it is simply equivalent to extending the N++ type channel stop layer 11 to the −X axis side. Therefore, it is not possible to improve the breakdown voltage of the peripheral region B10.

As shown in FIG. 13, the semiconductor device 1c of Comparative Example 3 has a semiconductor layer 12c containing N− type impurities of the same concentration as the N− type drift layer 10 on the N− type drift layer 10 in the second peripheral region B12. In this case, the portion of the semiconductor layer 12c also has a donor density that progresses depletion. In other words, it is essentially the same structure as Comparative Example 1. Consequently, the ionized donors included in the depletion layer extending from the P type semiconductor layer 13 side, such as the field limiting ring layer 13a, will cancel out with the ionized acceptors of the P type semiconductor layer 13, making it impossible to suppress inversion on the upper surface 101 side of the semiconductor substrate 100.

Unlike Comparative Examples 1 to 3, this embodiment has an N type guard ring layer 12 that can have a different potential from the N++ type channel stop layer 11 and the N− type drift layer 10, preventing complete depletion on the upper surface 101 side of the semiconductor substrate 100. Therefore, it is possible to suppress inversion of the upper surface 101 of the semiconductor substrate 100 and improve breakdown voltage.

Moreover, the N type guard ring layer 12 is arranged to be spaced apart from the N++ type channel stop layer 11. This results in a configuration where the spaced portion between the separated N type guard ring layer 12 and the N++ type channel stop layer 11 becomes depleted. When multiple N type guard ring layers 12 are arranged, each N type guard ring layer 12 may have a different potential. This configuration allows for improved breakdown voltage.

Specifically, the depletion layer wraps around below the N type guard ring layer 12, depleting up to the upper surface 101 of the spaced portion (excluding the inversion channel). However, before that, the configuration prevents avalanche breakdown at the end on the −X axis side of the N type guard ring layer 12 or the entire N type guard ring layer 12 from becoming depleted. Therefore, it is desirable to adjust the N type guard ring layer 12 to have an appropriate width in the X-axis direction.

For example, the lower limit of the width of the N type guard ring layer 12 is that not all of the multiple N type guard ring layers 12 become depleted. In other words, if the width of the multiple N type guard ring layers 12 is narrow, all of the N type guard ring layers 12 become depleted. Therefore, the width should be larger than the lower limit.

On the other hand, while the depletion layer spreads below the N type guard ring layer 12, the electric field at the end on the −X axis side of the N type guard ring layer 12 continues to rise. Therefore, the upper limit of the width of the N type guard ring layer 12 is that it does not undergo avalanche breakdown. In other words, if the width of the multiple N type guard ring layers 12 is wide, avalanche breakdown occurs at the end on the −X axis side before the depletion layer reaches the end on the +X axis side. Therefore, the width should be smaller than the upper limit.

The N-type guard ring layer 12 can function with just one ring, but it is preferable to arrange multiple N type guard ring layers 12 according to the breakdown voltage that should be borne outside the outermost structure when negative charges reach the upper surface 101. With only one N type guard ring layer 12, it is only possible to improve the breakdown voltage by adding a voltage of +α to the voltage necessary for the upper surface 101 (excluding the inversion channel) of the separation portion outside the N type guard ring layer 12 to become depleted. By widening the width of one N type guard ring layer 12 in the X-axis direction, it is possible to improve the breakdown voltage to some extent. However, if the width is too wide, the electric field at the inner corner of the N type guard ring layer 12 becomes too high, leading to avalanche breakdown, which in turn reduces the breakdown voltage. Therefore, there is a limit to the width of the N type guard ring layer 12.

By providing an equipotential ring 31 in the first peripheral region B11, it is possible to improve the breakdown voltage of the semiconductor device 1. However, when an N type guard ring layer 12 is present, the equipotential ring 31 may be considered unnecessary from the perspective of negative charge tolerance.

In the absence of an N type guard ring layer 12, from the perspective of negative charge tolerance, the equipotential ring 31 is extended on the semiconductor substrate 100 inside from the N++ type channel stop layer 11 to operate as a reverse field plate. On the other hand, when an N type guard ring layer 12 is present, if negative charges reach the upper surface 101, the breakdown voltage is supported in the portion where negative charges do not reach, below the extended portion of the equipotential ring 31. Therefore, the electric field becomes high at the end of the extended portion of the equipotential ring 31. For example, the equipotential ring 31 is placed directly above the N++ type channel stop layer 11, and the equipotential ring 31 is arranged not to extend inward from the N++ type channel stop layer 11. In other words, the inner end of the equipotential ring 31 is aligned with the inner end of the N++ type channel stop layer 11. Alternatively, the inner end of the equipotential ring 31 may be placed outside the inner end of the N++ type channel stop layer 11. With such a configuration, it is possible to support the voltage when negative charges reach the upper surface 101 with the N type guard ring layer 12. Thus, it is possible to suppress the application of a large electric field to the inner end of the equipotential ring 31.

When positive charges reach the upper surface 101, the depletion layer does not extend in the direction of the first peripheral region B11 or the second peripheral region B12, so there is no need to share the withstand voltage in the first peripheral region B11 or the second peripheral region B12 in the first place. The equipotential ring 31, as its name suggests, is originally intended to prevent the potential of the outer periphery of the element region A10 from becoming uneven along the outer periphery. Therefore, it is not a problem to narrow the width of the equipotential ring 31 to the extent that it does not impair its role. Also, if the impact of the potential of the outer periphery of the element region A10 becoming uneven is small, the equipotential ring 31 may not be necessary in extreme cases.

The semiconductor element in the element region A10 is an IGBT having an N type barrier layer 14, and if the ion implantation energy used to form the N type barrier layer 14 is sufficiently high and penetrates the second interlayer insulating film 22 or a part thereof (for example, LOCOS) already existing during the manufacturing process, the N type guard ring layer 12 may be formed in the same manufacturing process as the N type barrier layer 14. This can reduce manufacturing costs.

The N++ type channel stop layer 11 requires the injection of high-dose ions, making it difficult to introduce N type impurities through a thick interlayer insulating film such as LOCOS. On the other hand, when forming the first interlayer insulating film 21, it is particularly costly to provide a step to remove the material for forming the first interlayer insulating film 21 in the part where the second interlayer insulating film 22 already exists. Therefore, the thickness of the first interlayer insulating film 21 is made smaller than the thickness of the second interlayer insulating film 22. For example, after forming the part of the second interlayer insulating film 22 existing on the side of the semiconductor substrate 100, the remaining part of the second interlayer insulating film 22 and the first interlayer insulating film 21 are formed in the same process, making the thickness of the first interlayer insulating film 21 smaller than that of the second interlayer insulating film 22.

The interlayer insulating film in the peripheral region B10 may have positive charges fixed. The fixed positive charges in the interlayer insulating film suppress the extension of the depletion layer, allowing the distance between the outermost structure and the N++ type channel stop layer 11 to be narrowed, thereby reducing the size of the semiconductor device 1. For example, an interlayer insulating film can be formed using P-TEOS, and the positive charges generated in the P-TEOS can be fixed by RTA.

Although the disclosure made by the present inventor has been specifically described based on the embodiments, it is needless to say that the present disclosure is not limited to the embodiments and the modified examples, and various modifications can be made without departing from the gist thereof. For example, combinations of the configurations of the first embodiment as appropriate are also within the scope of the technical idea of the embodiment. Additionally, the following configurations are also within the scope of the technical idea of the embodiment.

### Additional Statement 1

A method of manufacturing a semiconductor device, comprising:
setting an element region including a semiconductor element and a peripheral region surrounding the element region in a semiconductor substrate having a first main surface and a second main surface opposite the first main surface, in plan view from the first main surface side;
forming, in the peripheral region of the semiconductor substrate, a drift layer of a first conductivity type and at least one annular channel stop layer of the first conductivity type arranged on the first main surface side relative to the drift layer, which annular channel stop layer surrounds the element region; and
forming at least one annular guard ring layer of the first conductivity type arranged on the first main surface side relative to the drift layer, which annular guard ring layer is arranged between an outermost peripheral structure within an interior surrounded by the channel stop layer and the channel stop layer,
wherein, in forming the guard ring layer:
the outermost peripheral structure is made to include at least one of an annular semiconductor layer of a second conductivity type arranged on the first main surface side relative to the drift layer in the semiconductor substrate, and an annular field plate containing conductive material arranged on the first main surface side relative to the semiconductor substrate; and
a concentration of impurities of the first conductivity type in the guard ring layer is made to be greater than a concentration of impurities of the first conductivity type in the drift layer and less than a concentration of impurities of the first conductivity type in the channel stop layer.

### Additional Statement 2

The method of manufacturing a semiconductor device according to Additional Statement 1, wherein, in forming the guard ring layer, the guard ring layer is formed to be spaced apart from the channel stop layer.

### Additional Statement 3

The method of manufacturing a semiconductor device according to Additional Statement 1, wherein, in forming the guard ring layer, the semiconductor substrate in the peripheral region is configured to include multiple guard ring layers, and the multiple guard ring layers are formed to be spaced apart from each other.

### Additional Statement 4

The method of manufacturing a semiconductor device according to Additional Statement 1, further comprising:
forming a first interlayer insulating film on the first main surface side relative to the semiconductor substrate in the peripheral region;
forming a contact groove in the first interlayer insulating film; and
forming the equipotential ring on the first main surface side relative to the first interlayer insulating film, including the conductive material;
wherein in forming the equipotential ring, the equipotential ring is formed to be connected to the channel stop layer via the contact groove.

### Additional Statement 5

The method of manufacturing a semiconductor device according to Additional Statement 4, wherein, in forming the equipotential ring, the guard ring layer is formed to be spaced apart from the equipotential ring in plan view.

### Additional Statement 6

The method of manufacturing a semiconductor device according to Additional Statement 1, wherein, in setting the element region including the semiconductor element and the peripheral region surrounding the element region,
the peripheral region is made to include:
a third peripheral region surrounding the element region;
a second peripheral region surrounding the element region and the third peripheral region; and
a first peripheral region surrounding the element region, the third peripheral region, and the second peripheral region,
wherein the method further comprises:
forming a first interlayer insulating film on the first main surface side relative to the semiconductor substrate in the first peripheral region; and
forming a second interlayer insulating film on the first main surface side relative to the semiconductor substrate in the second peripheral region, and
wherein, in forming the second interlayer insulating film, the thickness of the second interlayer insulating film is made to be greater than that of the first interlayer insulating film.

### Additional Statement 7

The method of manufacturing a semiconductor device according to Additional Statement 6, wherein, n forming the second interlayer insulating film, the second interlayer insulating film is configured to include LOCOS, and the guard ring layer is covered by the LOCOS.

### Additional Statement 8

The method of manufacturing a semiconductor device according to Additional Statement 1, wherein, further comprising:
forming multiple field limiting ring layers inside the area surrounded by the channel stop layer on the first main surface side relative to the drift layer in the semiconductor substrate of the peripheral region;
forming a third interlayer insulating film on the first main surface side relative to the semiconductor substrate;
forming multiple contact grooves in the third interlayer insulating film; and
forming multiple field plates on the first main surface side relative to the third interlayer insulating film,
wherein, in forming the field plates,
the multiple field plates are connected to the multiple field limiting ring layers via the multiple contact grooves, respectively, and;
the outermost peripheral structure includes at least one of the field limiting ring layers and the field plates arranged on the outermost periphery among the multiple field limiting ring layers and the multiple field plates.

### Additional Statement 9

The method of manufacturing a semiconductor device according to Additional Statement 1, further comprising:
forming semiconductor layer of a second conductivity type functioning as a termination structure on the first main surface side relative to the drift layer in the semiconductor substrate of the peripheral region, inside the area surrounded by the channel stop layer,
wherein in forming the semiconductor layer, the outermost structure includes the semiconductor layer.

### Additional Statement 10

The method of manufacturing a semiconductor device according to Additional Statement 1, further comprising forming the semiconductor element, wherein the semiconductor element includes the drift layer, and a floating layer of a second conductivity type disposed on the first main surface side relative to the drift layer,
wherein in forming the semiconductor element, the outermost peripheral structure includes the floating layer.

### Additional Statement 11

The method of manufacturing a semiconductor device according to Additional Statement 1, further comprising forming an interlayer insulating film on the first main surface side relative to the semiconductor substrate in the peripheral region,
wherein, in the step of forming the interlayer insulating film, the interlayer insulating film is designed to fix positive charges.

### Additional Statement 12

The method of manufacturing a semiconductor device according to Additional Statement 1, further comprising, wherein, in setting the element region containing the semiconductor element and the peripheral region surrounding the element region, the peripheral region includes:
a third peripheral region surrounding the element region;
a second peripheral region surrounding the element region and the third peripheral region; and
a first peripheral region surrounding the element region, the third peripheral region, and the second peripheral region,
wherein the method further comprises:
forming, in the third peripheral region:
a drift layer;
a field limiting ring layer of the second conductivity type arranged on the first main surface side relative to the drift layer;
a third interlayer insulating film provided on the first main surface side relative to the semiconductor substrate where the field limiting ring layer is arranged; and
a field plate provided on the first main surface side relative to the third interlayer insulating film;
forming, in the second peripheral region:
a drift layer;
a guard ring layer; and a second interlayer insulating film provided on the first main surface side relative to the semiconductor substrate where the guard ring layer is arranged; and
forming, in the first peripheral region:
a drift layer;
a channel stop layer;
a first interlayer insulating film provided on the first main surface side relative to the semiconductor substrate where the channel stop layer is arranged; and
an equipotential ring provided on the first main surface side relative to the first interlayer insulating film, which equipotential ring includes conductive material.

### Additional Statement 13

The method of manufacturing a semiconductor device according to Additional Statement 1, further comprising forming the semiconductor element as an IGBT in the element region, wherein the IGBT comprises:
a drift layer;
a barrier layer of the first conductivity type arranged on the first main surface side relative to the drift layer;
a body layer of the second conductivity type arranged on the first main surface side relative to the barrier layer;
an emitter layer of the first conductivity type arranged on the first main surface side relative to the body layer;
a trench gate electrode and a trench emitter electrode provided to sandwich the barrier layer, the body layer, and the emitter layer from both sides in one direction within a plane parallel to the first main surface;
a trench insulating film provided between the trench gate electrode and the semiconductor substrate, and between the trench emitter electrode and the semiconductor substrate; and
a floating layer of the second conductivity type provided on the opposite side of the barrier layer, the body layer, and the emitter layer across the trench gate electrode, and on the opposite side of the barrier layer, the body layer, and the emitter layer across the trench emitter electrode,
wherein, in forming the guard ring layer, the guard ring layer is formed simultaneously with the barrier layer in forming the IGBT.

### Additional Statement 14

The method of manufacturing a semiconductor device according to Additional Statement 13, wherein, in forming the guard ring layer, the guard ring layer is designed to include impurities of the same type as the impurities in the barrier layer.

### Additional Statement 15

The method of manufacturing a semiconductor device according to Additional Statement 13, wherein, in forming the guard ring layer, the guard ring layer is designed to include the same concentration of impurities as the concentration of impurities in the barrier layer.

### Additional Statement 16

The method of manufacturing a semiconductor device according to Additional Statement 1, wherein, the semiconductor element is designed to include at least one of a MOSFET and a diode.

### Additional Statement 17

The method of manufacturing a semiconductor device according to Additional Statement 1, further comprising forming a second interlayer insulating film on the first main surface side relative to the semiconductor substrate, wherein forming the guard ring layer involves introducing impurities of the first conductivity type into the semiconductor substrate through the second interlayer insulating film.

What is claimed is:

1. A semiconductor device comprising a semiconductor substrate having a first main surface and a second main surface opposite the first main surface, wherein the semiconductor substrate, in plan view from the first main surface side, comprises:
an element region containing a semiconductor element; and
a peripheral region surrounding the element region,
wherein the semiconductor substrate in the peripheral region includes:
a drift layer of a first conductivity type;
at least one annular channel stop layer of the first conductivity type arranged on the first main surface side relative to the drift layer and surrounding the element region; and
at least one annular guard ring layer of the first conductivity type arranged on the first main surface side relative to the drift layer and arranged between an outermost peripheral structure within an interior surrounded by the channel stop layer and the channel stop layer in plan view,
wherein the outermost peripheral structure includes at least one of an annular semiconductor layer of a second conductivity type arranged on the first main surface side relative to the drift layer and in the semiconductor substrate, and an annular field plate containing conductive material arranged on the first main surface side relative to the semiconductor substrate; and
wherein a concentration of impurities of the first conductivity type in the guard ring layer is greater than a concentration of impurities of the first conductivity type in the drift layer and less than a concentration of impurities of the first conductivity type in the channel stop layer.

2. The semiconductor device according to claim 1, wherein the guard ring layer is spaced apart from the channel stop layer.

3. The semiconductor device according to claim 1, wherein the semiconductor substrate in the peripheral region includes multiple guard ring layers, and the multiple guard ring layers are spaced apart from each other.

4. The semiconductor device according to claim 1, further comprising:
a first interlayer insulating film provided on the first main surface side relative to the semiconductor substrate where the channel stop layer is arranged, and
an equipotential ring provided on the first main surface side relative to the first interlayer insulating film and including the conductive material,
wherein the equipotential ring is connected to the channel stop layer through a contact groove formed in the first interlayer insulating film.

5. The semiconductor device according to claim 4, wherein the guard ring layer is spaced apart from the equipotential ring in plan view.

6. The semiconductor device according to claim 1, further comprising:
a first interlayer insulating film provided on the first main surface side relative to the semiconductor substrate where the channel stop layer is arranged, and
a second interlayer insulating film provided on the first main surface side relative to the semiconductor substrate where the guard ring layer is arranged,
wherein a thickness of the second interlayer insulating film is greater than a thickness of the first interlayer insulating film.

7. The semiconductor device according to claim 6, wherein the second interlayer insulating film includes LOCOS, and the guard ring layer is covered by the LOCOS.

8. The semiconductor device according to claim 1,
wherein the semiconductor substrate in the peripheral region includes multiple annular field-limiting ring layers of the second conductivity type arranged on the first main surface side relative to the drift layer and arranged within the interior surrounded by the channel stop layer,
wherein the semiconductor device further comprises a third interlayer insulating film provided on the first main surface side relative to the semiconductor substrate where the field-limiting ring layers are arranged,
wherein multiple field plates are connected to the multiple field-limiting ring layers through multiple contact grooves formed in the third interlayer insulating film, respectively, and
wherein the outermost peripheral structure includes one of the field-limiting ring layer and the field plate arranged on the outermost periphery, among the multiple field-limiting ring layers and the multiple field plates.

9. The semiconductor device according to claim 1,
wherein the semiconductor substrate in the peripheral region includes a semiconductor layer of the second conductivity type arranged on the first main surface side relative to the drift layer, functioning as a termination structure, and arranged within the interior surrounded by the channel stop layer, and
wherein the outermost peripheral structure includes the semiconductor layer.

10. The semiconductor device according to claim 1, wherein the semiconductor element includes:
a drift layer; and
a floating layer of the second conductivity type arranged on the first main surface side relative to the drift layer, and
wherein the outermost peripheral structure includes the floating layer.

11. The semiconductor device according to claim 1, further comprising an interlayer insulating film provided on the first main surface side relative to the semiconductor substrate in the peripheral region, wherein the interlayer insulating film is designed to fix positive charges.

12. The semiconductor device according to claim 1,
wherein the peripheral region includes:
a third peripheral region surrounding the element region;
a second peripheral region surrounding the element region and the third peripheral region; and
a first peripheral region surrounding the element region, the third peripheral region, and the second peripheral region,
wherein the third peripheral region includes:
the drift layer;
a field-limiting ring layer of a second conductivity type arranged on the first main surface side relative to the drift layer,
a third interlayer insulating film provided on the first main surface side relative to the semiconductor substrate where the field-limiting ring layer is arranged; and
the field plate provided on the first main surface side relative to the third interlayer insulating film,
wherein the second peripheral region includes:
the drift layer;
the guard ring layer; and
the second interlayer insulating film provided on the first main surface side relative to the semiconductor substrate where the guard ring layer is arranged,
wherein the first peripheral region includes:
the drift layer;
the channel stop layer;
a first interlayer insulating film provided on the first main surface side relative to the semiconductor substrate where the channel stop layer is arranged; and
an equipotential ring provided on the first main surface side relative to the first interlayer insulating film and including conductive material.

13. The semiconductor device according to claim 1,
wherein the semiconductor element includes an IGBT,
wherein the IGBT comprises:
the drift layer;
a barrier layer of the first conductivity type arranged on the first main surface side relative to the drift layer;
a body layer of the second conductivity type arranged on the first main surface side relative to the barrier layer; and
an emitter layer of the first conductivity type arranged on the first main surface side relative to the body layer;
a trench gate electrode and a trench emitter electrode provided to sandwich the barrier layer, the body layer, and the emitter layer from both sides in one direction in a plane parallel to the first main surface;
a trench insulating film provided between the trench gate electrode and the semiconductor substrate, and between the trench emitter electrode and the semiconductor substrate; and
a floating layer of the second conductivity type provided on the opposite side of the barrier layer, the body layer, and the emitter layer across the trench gate electrode, and on the opposite side of the barrier layer, the body layer, and the emitter layer across the trench emitter electrode.

14. The semiconductor device according to claim 13, wherein the guard ring layer contains a same type of impurity as the impurity in the barrier layer.

15. The semiconductor device according to claim 13, wherein the guard ring layer contains a same concentration of the impurity as a concentration of an impurity in the barrier layer.

16. The semiconductor device according to claim 1, wherein the semiconductor element includes at least one of a MOSFET and a diode.

17. A method of manufacturing a semiconductor device, the method comprising:
setting an element region including a semiconductor element and a peripheral region surrounding the element region in a semiconductor substrate having a first main surface and a second main surface opposite the first main surface, in plan view from the first main surface side;
forming, in the semiconductor substrate in the peripheral region, a drift layer of a first conductivity type and at least one annular channel stop layer of the first conductivity type arranged on the first main surface side relative to the drift layer and surrounding the element region; and
forming at least one annular guard ring layer of the first conductivity type arranged on the first main surface side relative to the drift layer and arranged between an outermost peripheral structure within an interior surrounded by the channel stop layer and the channel stop layer,
wherein, in forming the guard ring layer, the outermost peripheral structure is made to include at least one of an annular semiconductor layer of a second conductivity type arranged on the first main surface side relative to the drift layer in the semiconductor substrate, and an annular field plate containing conductive material arranged on the first main surface side relative to the semiconductor substrate; and
wherein a concentration of impurities of the first conductivity type in the guard ring layer is made to be greater than a concentration of impurities of the first conductivity type in the drift layer and less than a concentration of impurities of the first conductivity type in the channel stop layer.

18. The method according to claim 17, further comprising forming an IGBT as the semiconductor element in the element region,
wherein the IGBT is made to include:
the drift layer;
a barrier layer of the first conductivity type arranged on the first main surface side relative to the drift layer;
a body layer of the second conductivity type arranged on the first main surface side relative to the barrier layer;
an emitter layer of the first conductivity type arranged on the first main surface side relative to the body layer;
a trench gate electrode and a trench emitter electrode provided to sandwich the barrier layer, the body layer, and the emitter layer from both sides in one direction in a plane parallel to the first main surface;
a trench insulating film provided between the trench gate electrode and the semiconductor substrate, and between the trench emitter electrode and the semiconductor substrate; and
a floating layer of the second conductivity type provided on the opposite side of the barrier layer, the body layer, and the emitter layer across the trench gate electrode, and on the opposite side of the barrier layer, the body layer, and the emitter layer across the trench emitter electrode, and
wherein, in forming the guard ring layer, the guard ring layer is formed simultaneously with the barrier layer in forming the IGBT.

19. The method according to claim 17,
wherein, in setting the element region including the semiconductor element and the peripheral region surrounding the element region, the peripheral region is made to include:
a third peripheral region surrounding the element region;
a second peripheral region surrounding the element region and the third peripheral region; and
a first peripheral region surrounding the element region, the third peripheral region, and the second peripheral region,
wherein the method further comprises:
forming a first interlayer insulating film on the first main surface side relative to the semiconductor substrate in the first peripheral region; and
forming a second interlayer insulating film on the first main surface side relative to the semiconductor substrate in the second peripheral region,
wherein in forming the second interlayer insulating film, a thickness of the second interlayer insulating film is made to be greater than a thickness of the first interlayer insulating film.

20. The method according to claim 17, further comprising:
forming a second interlayer insulating film on the first main surface side relative to the semiconductor substrate,
wherein forming the guard ring layer includes introducing of an impurity of the first conductivity type into the semiconductor substrate through the second interlayer insulating film.
